(19) United States
(12) Patent Application Publication
(10) Pub. No.: US 2006/0257686 A1
(43) Pub. Date: Nov. 16, 2006

(54) Functional ink for relief printing and organic electroluminescence device and the manufacturing method

(76) Inventors: Takahisa Shimizu, Tokyo (JP); Koji Takeshita, Tokyo (JP); Hironori Kawakami, Tokyo (JP)

Correspondence Address: SQUIRE, SANDERS & DEMPSEY L.L.P., 1 MARITIME PLAZA, SUITE 300, SAN FRANCISCO, CA, 94111, US

(21) Appl. No.: 11/432,032

(22) Filed: May 10, 2006

(30) Foreign Application Priority Data
May 13, 2005 (JP) 2005-140784

(51) Int. Cl. H01L 51/50; C09K 11/02; H01L 51/56

(52) U.S. Cl. 428/690; 428/917; 313/504; 313/506; 427/66; 252/301.16; 252/301.35; 257/E51.035; 257/E51.033

(57) ABSTRACT

In functional inks for relief printing concerning the present invention, contents of compositions of functional layers can be 1.0-2.5 wt %. In addition, viscosity of functional ink for relief printing can be 15-50 mPa·s. Therefore, each functional layer can be formed with uniformity and reasonable thickness.

### CROSS REFERENCE

This application claims priority to Japanese application number 2005-140784, filed on May 13, 2005, which is incorporated by reference.

### BACKGROUND OF THE INVENTION

1. Field of the Invention

The present invention is related to functional ink for relief printing and an organic electroluminescence device. The present invention is also related to the manufacturing method for the formation of one part or all of an organic luminescence media layer of organic electroluminescence device by relief printing method.

2. Description of the Related Art

Electric current is applied to an organic luminous layer of electroconductivity. Then a hole couples to poured electron again. In this recombination, organic luminescent material comprising the organic luminous layer emits light.

In the case of application of electric current to the organic luminous layer, it is necessary to take the light outside. Therefore a transparent electrode and an opposed electrode are installed on either side of the organic luminous layer.

This device is a layer stack of the transparent electrode and the organic luminous layer. The opposed electrodes are laminated by this sequence on a transparent substrate. Usually, transparent electrode is used as an anode, and the opposed electrode is utilized as a cathode.

Even more particularly, it is often that the following constitution of organic electroluminescence device is adopted to improve luminous efficiency. Functional layer such as a hole transport layer and a hole injection layer is provided between the anode and the organic luminous layer. Functional layer such as an electronic transport layer and an electron injection layer is provided between the organic luminous layer and the cathode. The organic luminous layer and the hole transport layer, a hole injection layer, an electron transport layer and an electron injection layer are referred to as an organic luminescence media layer.

Low molecular organic compounds are used for functional materials comprising the hole transport layer, the organic luminous layer and the electron transport layer. It is necessary for these layers to be uniform thin film of thickness of several decades nm to several hundred nm to efficiently emit light as an organic electroluminescence device. Therefore, these layers can be formed by vacuum evaporation such as resistance heating method. However, this method, using low molecular organic compound, needs the large-scaled vacuum evaporation system to which evaporation kettles are coupled. This results in low productivity and high cost of manufacturing. In addition, high resolution patterning of these organic luminescence media layers is necessary to make a display unit of matrix display by organic electroluminescence device. Especially, high resolution patterning of the organic luminous layer is necessary. A minute mask is needed to form minute pattern-shaped thin film by resistance heating evaporation. As much as the substrate on which the thin film was formed upsized, patterning accuracy became worse.

On the other hand, there is the macromolecule Electroluminescence device having functional materials that are polymeric materials. By way of example only, luminescent materials used for the organic luminous layer include low molecular fluorescent dye that dissolves in polymers and polymeric luminescent material.

These polymeric materials are dissolved in a solvent, and ink can be made. By coating/printing under air pressure of this ink, thin film can be formed. As against the above-mentioned evaporation of low molecular material, facility cost of the method to use polymeric materials is cheap, and productivity is high.

As methods of coating, spin coat method, dipping, bar coat method and slit coat (die coat) method are generally exemplified. However, when polymeric material is applied by these methods, it is difficult to form thin film of uniform thickness in larger area. It is necessary to form thin film of uniform thickness in larger domain so that organic electroluminescence device emits light uniformly. In addition, due to coating of ink to a whole area of a substrate, it is necessary to remove ink on electrode takeout parts. In addition, by these application methods, only one kind of functional layer can be formed in one layer. Therefore, in order to make three primary colors display, it is necessary to use color filter. Therefore, a cost of member is high.

The following coating is difficult by these wet coating methods: The formation of high resolution pattern; and pattern formation of three colors of RGB which are separated.

On the other hand, printing method is suitable for the formation of separated pattern and the formation of high resolution pattern. Therefore, thin film formation by a printing method is more effective.

As a printing method, various printing methods such as an intaglio printing, relief printing, lithography and screen printing are exemplified. As for the organic electroluminescence device, it is often that a glass substrate is used as a substrate supporting-the electrodes. Gravure printing uses hard metal printing plate. Therefore, in gravure printing, there is danger that a substrate is damaged. In addition, the use of a metallograph increased the cost. In addition, exchange of printing plate is not easy.

The offset printing that is lithography is not suitable for the formation of an organic luminescence media layer due to ink viscosity.

Screen printing is not suitable for the formation of an organic luminescence media layer due to ink viscosity. Even more particularly, screen printing has low accuracy as compared to other printing processes. Therefore, it is difficult to form thin film of less than or equal to 0.1 μm that is the film thickness which is necessary for each functional layer.

Thus, as the printing method that can form each functional layer, relief printing method attracts attention. (Japanese Patent Laid-Open No. 2001-155858 Official Gazette) However, composition or viscosity of the ink is not examined until now.

Especially, the ink which can uniformly form each functional layer of thickness of less than or equal to 0.1 μm in a pixel surrounded with an insulator layer on a substrate has not examined at all.

### SUMMARY OF THE INVENTION

The present invention provides the ink which can form a functional layer comprising an organic luminescence media layer of a uniform and reasonable thickness. The functional layer can include any one or combination of a hole transport layer, an organic luminous layer and an electron transport layer. In addition, in some embodiments the functional layer should have a thickness of less than or equal to 0.1 μm. In addition, the present invention provides an organic electroluminescence device and a manufacturing method.

In functional inks for relief printing concerning the present invention, contents of compositions of functional layers are 1.0-2.5 wt %. In addition, in some embodiments, viscosity of functional ink for relief printing is 15-50 mPa·s at room temperature. Therefore, each functional layer can be formed with uniformity and reasonable thickness.

In a pixel surrounded especially by means of walls of insulating properties such as partition walls, each functional layer having a thickness is less than or equal to 0.1 μm can be uniformly formed. In the case of the formation of each functional layer, influence of surface tension of ink and influence of bleeding is controlled.

### BRIEF DESCRIPTION OF DRAWINGS

FIG. 1A is a cross-section of the organic electroluminescence device having a functional layer formed by using functional ink for relief printing of an embodiment of the present invention.

FIG. 1B is a cross-section of the organic electroluminescence device having a functional layer formed by using functional ink for relief printing of an embodiment of the present invention.

FIG. 1C is a cross-section of the organic electroluminescence device having a functional layer formed by using functional ink for relief printing of an embodiment of the present invention.

FIG. 2 is an example of a relief printing device used in some embodiments of the present invention.

### DESCRIPTION OF THE PREFERRED EMBODIMENT

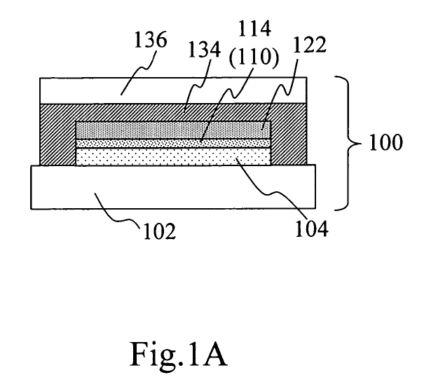

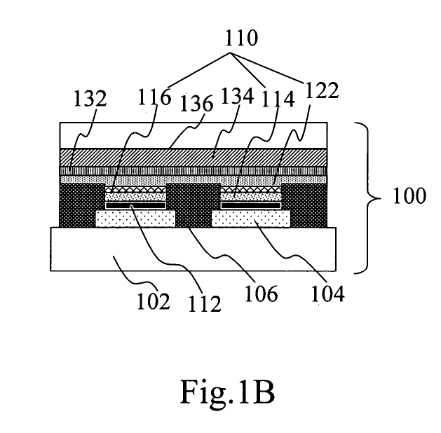

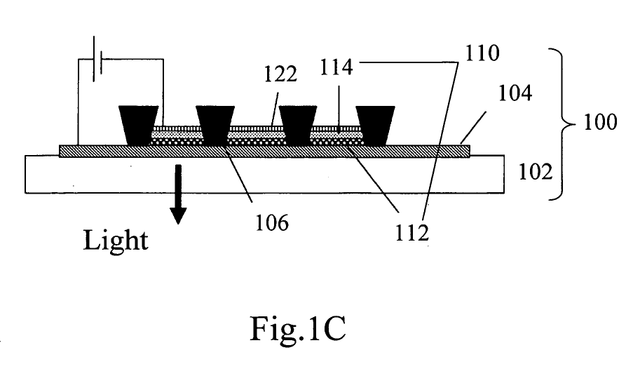

Profiles of some embodiments of an organic electroluminescence device of the present invention is shown in FIG. 1A, FIG. 1B and FIG. 1C. Organic electroluminescence device 100 of the present invention can include organic luminescence media layer 110 between the first electrode 104 and the second electrode 122. Organic luminescence media layer 110 can include an organic luminous layer 114. Even more particularly, organic luminescence media layer 110 can include a hole injection layer, a hole transport layer, an electron blocking layer, a buffer layer, a hole blocking layer, an electron transport layer and an electron injection layer by reason of improvement of luminous efficiency. The organic luminous layer and layers for luminous efficiency improvement are referred to as functional layer respectively.

Functional Ink for Relief Printing

Functional ink for relief printing concerning the present invention is used in the formation of functional layer. Functional ink can have a of solvent and a functional material dissolved in the solvent. Functional materials include organic luminescent material, a hole transport material and an electron transport material. Depending on a kind of functional material, organic luminescence ink, hole transport ink or electron transport ink can be made. Functional layer made of these inks is referred to as an organic luminous layer, a hole transport layer or an electron transport layer respectively.

On the other hand, hole transport-related luminescence ink including both organic luminescent material and hole transport material can be made. Hole transport-related luminescence ink is used, and hole transport characteristics luminous layer can be formed. In other words, a layer having plural functions made from plural materials can be formed.

In addition, functional material having plural functions can be used. By way of example only, ink including hole injection transportation material is used, and a hole injection transport layer can be formed.

In addition, for example, a hole injection material, an electron injection material, an electronic block material, a hole block material and an insulating material are used, and a hole injection layer, an electron injection layer, an electron blocking layer, a hole blocking layer and an insulator layer can be formed by relief printing method with the use of a plastic plate.

Hole Transport Ink

A hole transport layer is exemplified as a functional layer. Hole transport ink for the formation of a hole transport layer includes a solvent and hole transport material dissolved in the solvent.

As hole transport material, the following low molecular weight compounds are exemplified:

Copper phthalocyanine and the derivative;

and low molecular weight compounds such as the following aromatic amine system:

1,1-bis (4-di-p-tolylamino phenyl) cyclohexane; and N, N′-diphenyl-N, N′-bis (3-methylphenyl)-1,1′-biphenyl-4,4′-diamine; and N, N′-di(one-naphthyl)-N, N′-diphenyl-1,1′-biphenyl-4,4′-diamine.

In addition, polymeric materials such as polyaniline, polythiophene and polyvinylcarbazole can be used as hole transport material. In addition, admixture with poly (3,4-ethylenedioxy thiophene) and polystyrene sulfonate may be used.

Organic Luminescence Ink

An organic luminous layer is exemplified as a functional layer. Organic luminescence ink for the formation of the organic luminous layer can include a solvent and an organic luminescent material dissolved in the solvent. The organic luminescent material which fluorescent coloring agent dissolved in macromolecule can be used. As fluorescent coloring agent, coumarin corollary, perylene corollary, pyran system, anthrone corollary, polphilene corollary, quinacridon corollary, N, N′-dialkyl displacement quinacridon corollary, naphthalimido corollary, and N, N′-diaryl displacement pyrrolo pyrrole series are exemplified. As macromolecule, polystyrene, polymethyl methacrylate and polyvinylcarbazole are exemplified. In addition, macromolecule fluorescent substance such as PPV system and PAF system, polyparaphenylene corollary can be used. In addition, existing organic luminescent material can be used.

Electron Transport Ink

Electron transport layer is exemplified as a functional layer. Electron transport ink for the formation of an electron transport layer includes a solvent and electron transport material dissolved in the solvent. As electron transport material, the material which N, N′-di(one-naphthyl)-N, N′-diphenyl-1,1′-biphenyl-4,4′-diamine dissolves in macromolecule such as polystyrene, polymethyl methacrylate and polyvinylcarbazole can be used.

Functional ink for relief printing concerning the present invention includes functional material such as hole transport material, organic luminescent material and electron transport material in a solvent. Content of functional material can be from 1.0% by weight to 2.5% by weight. By addition of viscosity modifier, viscosity of functional ink is adjusted to less than 50 mPa·s and more than 15 mPa·s at room temperature.

When content of functional material is less than 1.0% by weight, each functional layer does not function sufficiently. Thus, luminescence of organic electroluminescence device is insufficient. On the other hand, when content of functional material is beyond 2.5% by weight, viscosity of ink is not suitable for relief printing method. Therefore, in this case, it is difficult to form functional layer by printing.

As the solvent which can be applied to functional ink concerning the present invention, solvent of vapor pressure of less than or equal to 25 mmHg at 25 degrees Celsius is preferred. As such a solvent, tetralin, cyclohexylbenzene, methyl benzoate and ethyl benzoate can be exemplified. These solvent simple substances (in other words, 100%) may be used, but solvent mixed with other solvent can be used. As other solvent, toluene, acetone, methyl ethyl ketone, methyl isobutyl ketone, methanol, ethanol, isopropyl alcohol, ethyl acetate and butyl acetate can be exemplified.

It is preferable for functional ink concerning the present invention to add viscosity modifier if necessary. Polystyrene, or polyvinylcarbazole can be used as such a viscosity modifier.

In addition, functional ink bonds to an unnecessary part in a substrate by flowability of functional ink when viscosity of controlled functional ink does not reach 15 mPa·s at room temperature. Therefore, the formation of pattern is not good. In addition, each functional layer of suitable thickness cannot be formed. As discussed below, functional ink rises along side surface of the insulator layer by surface tension of the functional ink when a pixel is sectioned by the partition wall installed in on the substrate. A central portion of functional layer sectioned by the insulator layer is thin. Functional layer near the insulator layer is thick. As a result, the function layer thickness in a pixel is nonuniform. In addition, functional ink may flow over this insulator layer, and it may come out in a neighboring pixel.

On the other hand, bleeding occurs by means of printing pressure of relief printing when viscosity of functional ink is beyond 50 mPa·s at room temperature. Therefore, middle of streak is thin, and a penumbra of streak is thick, and a layer of uniform thickness is not provided. When a pixel is sectioned by an insulator layer, functional layer of nonuniform thickness is formed by this bleeding. In other words a central portion of a part sectioned by an insulator layer is thin, and a penumbra near an insulator layer is thick.

On the other hand, each functional layer of uniform thickness can be formed when viscosity of functional ink is 15 mPa·s-50 mPa·s at room temperature. In addition, each functional layer of uniform thickness can be formed when a pixel is divided by an insulator layer. Rheometer was used, and viscosity was measured at rate of shear 100-200 s⁻¹.

Detergent, antioxidant, and UV absorber can be added in functional ink for this relief printing other than viscosity modifier if necessary.

Relief Printing Method

A description is made of a printing process using functional ink for relief printing concerning the present invention.

Functional ink for relief printing concerning the present invention can be used to form functional layer comprising an organic luminescence media layer comprising organic electroluminescence device by relief printing method.

Relief printing plate is used as printing plate. Ink is held in convex parts of the printing plate. Ink is put from the convex part on to a substrate. Conventionally, a metal such as ferrum or lead has been used as material of the printing plate. In late years an inexpensive, light photosensitive resin has been used. In addition, as an example of relief printing method, the flexography that material of printing plate is rubber or a photosensitive resin is exemplified. Relief printing plate made of a photosensitive resin is referred to as plastic plate in the present specification. Ink for relief printing of the present invention is used as optimum in relief printing method with the use of this plastic plate.

In this printing process, metal relief printing plate can be used as well. However, crack may occur in a substrate by pressing force in printing when a substrate is made of weaker materials such as glass. Therefore, it is desirable to utilize printing plate made of resin.

A manufacturing method of printing plate made of such a resin is explained as follows. A layer of a photosensitive resin is laminated on a substrate of high dimensional stability such as a polyester film. Subsequently a photosensitive resin is exposed through the mask such that light transmits only in streak part. Then streak part is stiffened. And unexposed non-hardening part is washed away with liquid developer such as a solvent. In this manner photosensitive resin relief printing plate can be obtained.

Organic luminescent material of polymer system does not dissolve well in an organic solvent of a water system or alcohol system. In addition, there is harmful effect in the luminescence property when organic luminescent material of polymer system dissolves in an organic solvent of a water system or alcohol system. Therefore it is necessary to dissolve organic luminescent material of polymer system in an organic solvent when the ink which was suitable for coating and printing is made. As this organic solvent, aromatic organic solvent such as toluene or dimethylbenzene is preferred. Thus, among functional ink, organic luminescence ink is ink including an aromatic organic solvent. Swelling of relief printing plate by this organic solvent should be prevented. And it should be printed so that streak is precise. Therefore it is desirable to use relief printing plate having resistance against an organic solvent.

It is preferable to use hydrophilic resin as material of such a relief printing plate. Depending on development method, there are the following two kinds of photosensitive resins: the photosensitive resin which can be developed with water; and the photosensitive resin which can be developed with an organic solvent.

A photo-curing type photosensitive resin of water development type is applied to a substrate. And exposure/development are done. Water development type plastic plate made in this way can be used. A water development type photosensitive resin remains hydrophilic after it was hardened. Thus, swelling by oil solubility solvent in functional ink can be prevented.

As such a water development type photo-curing type photosensitive resin, mixture of hydrophilic polymer and polymer having unsaturated bonding can be exemplified. As hydrophilic polymer, polyamide, polyvinyl alcohol, and a cellulose derivative can be exemplified. In addition, as unsaturated bonding, vinyl bonding can be exemplified. As polymer having vinyl bonding, methacrylate system polymer can be exemplified. Photoresponsive initiator may be mixed in this water development type photo-curing type photosensitive resin. Aromatic carbonyl compound can be used as photoresponsive initiator.

In addition, when a substrate is glass, it is preferable to use soft plastic plate. On the other hand, when a substrate is various plastic sheeting, a plastics film, printing plate except plastic plate can be used. This is because as plastic sheeting, plastic films are hard to break.

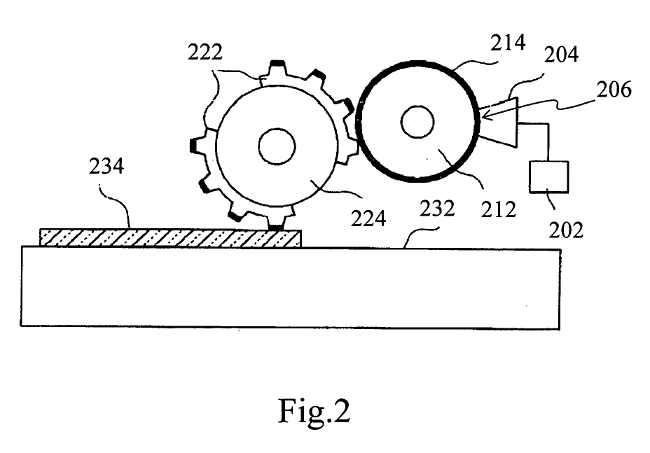

A schematic illustration of relief printing device is shown in FIG. 2. This relief printing device prints functional ink including functional material on a substrate. This relief printing device has ink tank 202, ink chamber 204, anilox roll 212 and plate cylinder 224 that printing material 222 is equipped with. Printing material 222 includes plastic plate. Functional ink is taken to ink tank 202. Functional ink is sent into ink chamber 204 from ink tank 202. Anilox roll 212 contacts with ink feed section 206 of ink chamber 204, and it is rotatably supported.

With rotation of anilox roll 212, ink layer 214 of functional ink supplied in anilox roll surface is formed in uniform thickness. The ink of this ink layer is transferred to a convex part of printing material 222 rotationally driven in proximity to anilox roll. Substrate 234 is transported to printing position of flat-bed printing machine 232 by the transporting means that are not illustrated. And ink on a convex part of printing material 222 is printed to substrate 234. Thickness of functional layer formed in this way is 50 nm-100 nm, and preferably it is 50 nm-80 nm. Ink including organic luminescent material of a different luminescent color is used, and printed multiple times. In this way organic electroluminescence device of color display can be produced.

Organic Electroluminescence Device

Primary organic electroluminescence device concerning some embodiments of the present invention include a substrate, the first electrode, the organic luminous layer, and the second electrode. The sequence can be as listed. The organic luminous layer is formed on a substrate by relief printing using the organic luminescence ink having an organic luminescent material dissolved in an organic solvent.

In addition, secondary organic electroluminescence device concerning some embodiments of the present invention includes a substrate, the first electrode, and an organic luminescence media layer, and the second electrode. The sequence can be as is listed. Organic luminescence media layer includes the organic luminous layer. In addition, organic luminescence media layer includes a hole transport layer and/or an electron transport layer. In other words, organic luminescence media layer can have a number of functional layers. Functional ink can contain a solvent, functional material such as organic luminescent material, hole transport material and electron transport material dissolved in the solvent.

Functional ink may contain only one functional material. In addition, functional ink may contain a plurality functional materials. In some embodiments, percentage of functional material is less than 2.5% by weight and more than 1.0% by weight. Viscosity of functional ink is less than 50 mPa·s and more than 15 mPa·s at room temperature. This functional ink is printed on a substrate by means of relief printing method, and either of the plural functional layer can be formed. Profile of the organic electroluminescence device which includes a substrate, the first electrode, an insulator layer, a hole transport layer, the organic luminous layer and the second electrode is shown in FIG. 1B and FIG. 1C.

Substrate

Organic electroluminescence device 100 of the present invention has substrate 102 as illustrated in FIG. 1A, FIG. 1B and FIG. 1C.

Substrate having some intensity can be used as this substrate 102. In some embodiments, a glass plate, a plastics film and a plastic sheeting can be used.

The organic luminous layer is easy to deteriorate with oxygen and moisture. Thus, thin glass plate of thickness of 0.2-1 mm is preferable. In this case, oxygen barrier properties and steam barrier properties of glass plate are high. Therefore, thin organic electroluminescence device without degradation can be made. In addition, in the case of organic electroluminescence device of bottom emission type, material having translucency is selected as a substrate.

In addition, when substrate 102 is a flexible plastics film, organic electroluminescence device can be produced on a reel up type film. Therefore, productivity is high, and an inexpensive device can be provided.

As a plastics film, polyethylene terephthalate, polypropylene, cyclo-olefin polymers, polyamide, polyether sulfone, polymethyl methacrylate and polycarbonate can be used.

In addition, first electrode 104 described below is formed on one face of substrate 102, and a film having gas barrier properties can be laminated in the other face of substrate 102. Then barrier properties improve more, and organic electroluminescence device of a long life time can be made.

The following film can be used as a gas barrier properties film: a film deposited ceramic; and a single-layer film such as polyvinylidene chloride, polyvinyl chloride or ethylene-vinyl acetate copolymer saponification material; and a film comprising plural layers of these films.

Before the formation of the first electrode, the above described gas barrier properties film is formed by methods such as chemical vapor deposition directly on one face or both sides of film substrate.

First Electrode

Organic electroluminescence device 100 of some embodiments of the present invention has the first electrode 104 on substrate 102 as illustrated in FIG. 1A, FIG. 1B and FIG. 1C.

First electrode 104 should be thin, uniform conductive film.

Examples of first electrode 104 are described. Complex oxide (ITO) of indium and tin can be formed by evaporation or sputtering method on translucency substrate 1. In addition, first electrode 104 can be formed by “coating and thermal decomposition method”. By way of example only, precursor such as octylic acid indium or acetone indium is applied on substrate. An oxide is formed by thermal decomposition afterwards.

Or metal such as aluminium, gold and silver may be evaporated in semitransparency.

In addition, organic semiconductors such as polyaniline can be used.

In the case of bottom emission type, electrode of transparence or semitransparency can be used as first electrode.

When first electrode is anode pouring a hole, a material having a high work function should be selected.

FIG. 1A is the figure which showed profile of organic electroluminescence device in accordance with one embodiment. Patterning of first electrode 104 is not done, and an insulator layer is not installed.

In addition, patterning of this first electrode 104 can be performed if necessary. In patterning, a mask of a photosensitive resin can be used, and the first electrode 104 is etched. In some embodiments, in one particularly in the case of passive matrix driving, stripe-shaped first electrode can be provided. In FIG. 1C, configuration of first electrode 104 is form of stripe which is parallel in page surface.

Before forming the next layer, surface treatment such as UV processing or plasma treatment can be performed if necessary.

Insulator Layer

A substrate may include insulator layer 106 corresponding to a pixel. An insulator layer is a wall of insulating properties of some height formed on the substrate on which the first electrode is formed. Partition wall sections each pixel comprising organic electroluminescence device. Partition wall prevents functional layer of each pixel from coming out to a neighboring pixel. In addition, an insulator layer covers an end of pattern-shaped first electrode. Therefore, an insulator layer prevents a short circuit between the second electrode and an end of the first electrode such as ITO. FIG. 1B is the figure which shows an embodiment of the profile of the organic electroluminescence device. First electrode 104 is form of a pattern. Matrix-shaped insulator layer 106 is comprised to cover an end of first electrode 104.

In addition, FIG. 1C is the figure which a stripe-shaped first electrode and stripe-shaped insulator layer are installed. In FIG. 1C, stripe-shaped first electrode is perpendicular to a stripe-shaped insulator layer.

Photoresist having photosensitivity and insulating properties is applied on a substrate provided with the first electrode. After having exposed an insulator layer through a mask, an insulator layer is developed. In this way an insulator layer is formed.

In some embodiments, photoresist of negative type is used. Photoresist is exposed through a mask from the applied side. In this way, the insulator layer that a section is form of reverse taper as shown in FIG. 1C can be formed.

According to the process of the present invention, pattern-shaped functional layer is formed by a printing method. Even if height of an insulator layer is 10 μm-0.5 μm, mixed color and white emission can be prevented. In addition, organic luminescence ink can be filled in domain sectioned by an insulator layer.

And because ink is filled in domain sectioned by the insulator layer having a height of 10 μm-0.5 μm by means of a printing method, there is the following merit.

In manufacture of functional layer, mixed color and white emission can be sufficiently prevented. When second electrode and a layer for sealing are laminated, step between an insulator layer and pixel parts is small. Therefore, the organic electroluminescence device having a long life time can be produced. In addition, yield of manufacture of organic electroluminescence device is high.

In addition, as the substrate on which the functional layer is printed, a TFT substrate comprising the following member can be used: a substrate, thin film transistor (TFT) on a substrate corresponding to each pixel, an insulator layer covering TFT and pixel electrodes (the first electrodes) of form of pattern corresponding to each pixel.

In this case, it is desirable to form an insulator layer of the lattice shape which covers an end of pixel electrodes to prevent a short circuit.

Organic Luminescence Media Layer

Organic electroluminescence device 100 of the present invention includes organic luminescence media layer 110. Organic luminescence media layer comprises one or more functional layers. One layer of functional layer can be the organic luminous layer including organic luminescent material.

In addition, the following layers can be included:

A hole transport layer including hole transport material, a hole injection layer including hole injection material, an electron transport layer including electron transport material, an electron injection layer including electron injection material, as well as the luminescence assistance layers such as an electron blocking layer, a hole blocking layer and an insulator layer.

As constitution of organic luminescence media layer, the following constitution can be exemplified:

The organic luminescence media layer which includes only an organic luminous layer as illustrated in FIG. 1A;

(1) The organic luminescence media layer which is combined with a hole transport layer and an organic luminous layer as illustrated in FIG. 1C;

(2) The organic luminescence media layer which is combined with a hole transport layer and organic electron transport property luminous layer;

(3) The organic luminescence media layer which is combined with a hole transport layer, an organic luminous layer and a electron transport layer as illustrated in FIG. 1B.

One functional layer can have a plurality of functions such as hole transport and luminescence.

Functional ink of the present invention is used, and one layer of these functional layers is formed at least by means of relief printing method.

In this way, organic luminescence media layer 110 may include a hole transport layer between the anode and an organic luminous layer.

Hole transport ink of the present invention which hole transport material dissolves in a solvent is used, and hole transport layer 112 can be formed by a method such as spin coat, a gravure printing method, inkjet method and slit coat method. In addition, other hole transport ink which are known to one having skill in the art may be used. However, it is desirable to form hole transport layer 112 by means of relief printing method using hole transport ink concerning the present invention. In addition, depending on a kind of material, dry coating means such as evaporation can be used.

Organic luminescence media layer 110 which comprises organic electroluminescence device 100 of the present invention comprises an organic luminous layer including organic luminescent material. Organic luminescence ink of the present invention which organic luminescent material dissolves in a solvent is used, and organic luminous layer 114 can be formed by a method such as spin coat, a gravure printing method, inkjet method and slit coat method. In addition, other organic luminescence ink which is known to one of ordinary skill in the art can be used. However, it is desirable to form organic luminous layer 114 by relief printing method using organic luminescence ink concerning the present invention. In addition, depending on a kind of material, dry coating means such as evaporation can be used.

Organic luminescence media layer 110 which comprises organic electroluminescence device 100 of the present invention may include electron transport layer 116 between the organic luminous layer and cathode. Electron transport ink of the present invention which electron transport material dissolves in a solvent is used, and the electron transport layer can be formed by a method such as spin coat, a gravure printing method, inkjet method and slit coat method. In addition, other electron transport ink known to one of ordinary skill in the art can be used. However, it is desirable to form electron transport layer 116 by means of relief printing method using electron transport ink concerning the present invention. In addition, depending on a kind of material, dry coating means such as evaporation can be used.

In some embodiments, the total thickness of organic luminescence media layer 110 comprising hole transport layer 112, organic luminous layer 114 and electron transport layer 116 is lower than 1 μm, and preferably it is lower than 0.15 μm. In some embodiments, the lower limit can be more than 0.05 μm. It is necessary to form at least one functional layer by relief printing method using functional ink for relief printing concerning the present invention. In addition, if printing speed and discharge volume of ink onto printing plate are optimized, the uniform coat having a thickness unevenness equal to or less than ±0.01 μm can be formed.

Second Electrode

Next, second electrode 122 is formed as illustrated in FIG. 1A, FIG. 1B and FIG. 1C.

When the second electrode is cathode provided over the organic luminous layer and the electron transport layer, the following material can be used: the material that electron injection efficiency to functional layer such as electron transport layer is high and work function is low.

By way of example only, metal such as Mg, Al and Yb can be used. In addition, the following second electrode may be used: thin layer such as Li or LiF of film thickness about 1 nm is provided on the surface of organic luminescence media layer; and the metal membrane with high chemical stability is laminated on this thin layer. Al and Cu are examples of stable metals.

In addition, the following material can be used as material of second electrode to balance stability with electron injection efficiency: alloy with a metal that has low work function and a metal which is stable.

For example, MgAg, AlLi, and CuLi can be used as such an alloy.

This second electrode can be formed by methods such as resistance heating evaporation method, electron beam method and sputtering method. It is desirable for thickness of the second electrode to be about 10-1000 nm. In the case of organic electroluminescence device of so-called top emission type, second electrode such as the following can be used: material with translucency is used as material of the second electrode.

By means of forming extremely thin membrane, the second electrode that transmits light is formed.

Second electrode 122 can be formed selectively in area of a pixel of organic electroluminescence device. By way of example only, second electrode 122 can be formed in predetermined configuration by evaporating through a mask.

In FIG. 1C, second electrode 122 is formed in the direction which is perpendicular to first electrode 104. Second electrode 122 can be formed between stripe-shaped insulator layer 106. Second electrode 122 is form of stripe in correspondence with a pixel.

Second electrode 122 can be formed by evaporating from the upper part of the stripe-shaped insulator layer having a profile that is reverse taper configuration. Second electrode is formed in divided configuration in correspondence with configuration of an insulator layer by such an evaporation. Therefore, configuration of second electrode is configuration of the stripe which is perpendicular to first electrode.

In addition, for example, second electrode can be formed in the shape of stripe by a well-known photolithography method.

Process to Seal

Because electric current flows to the organic luminous layer between electrodes, organic electroluminescence device emits light.

However, the organic luminous layer deteriorates easily by means of atmospheric moisture and oxygen. Thus a seal is usually installed on the organic luminous layer to isolate the organic luminous layer from the outside.

A seal can be made as follows: Substrate 136 for sealing can be adhesively bonded by adhesive 134 as illustrated in FIG. 1A.

Thin film 132 for sealing on the second electrode side may be provided more as illustrated in FIG. 1B.

Example of thin film 132 for sealing is described below.

Inorganic thin film can be used. In some embodiments, by means of CVD method, silicon-nitride film of thickness 150 nm is layered on second electrode directly.

About sealing by thin film, it is preferable to complete sealing only with thin film. When organic electroluminescence device is sealed only by thin film, manufacturing process of organic electroluminescence device can be simplified. In addition, organic electroluminescence device can be formed thinly.

The following adhesive can be used as adhesive 134: Photo-curing type adhesive property resin, heat curing type adhesive property resin and 2 fluid hardening type adhesive property resin comprising epoxy system resin, acrylic resin, silicone oil and the like, acrylic resin such as ethylene ethylacrylate (EEA) polymer, vinyl resin such as ethylene vinyl acetate (EVA), thermoplastic resin such as polyamide and synthetic rubber, thermoplastic adherent resin such as acid denaturing agents of polyethylene or polypropylene.

A method to form an adhesive layer on second electrode 122 or thin film 132 for sealing is described below.

Solvent solution method, “pushing out” laminate method, fusion/hot melt method, calendar method, nozzle application method, screen printing, vacuum laminate method and heated roll laminate method can be used.

When resin of ultraviolet cure type is used and thin film for sealing is bonded to second electrode, the organic luminous layer is not heated. Therefore, degradation of the organic luminous layer by heat does not occur. In addition, organic electroluminescence device is a layer stack of material of various coefficient of thermal expansion. Modification of organic electroluminescence device and break-down of some layer can be prevented.

On the other hand, luminescent material deteriorates due to ultraviolet radiation. Therefore, adhesive is placed at area except domain emitting light as a pixel. Ultraviolet radiation is irradiated in area except a light emitting area. By way of example only, in the case of irradiation, masking means such as masks can be used.

Material having hygroscopicity and character absorbing oxygen can be incorporated into adhesive if necessary.

Depending on size and configuration of an organic electroluminescence display unit to seal, thickness of adhesive is decided. In some embodiments, the thickness of adhesive is about 5-500 μm.

Adhesive can be placed at a whole area of substrate for sealing. In addition, adhesive can be formed in the shape of frame to seal the surroundings.

Substrate 136 for sealing should be of the type that transmissivity of moisture and oxygen is low. The following material can be used as material of substrate 136 for sealing: Ceramics such as alumina, silicon nitride and boron nitride, glass such as a no alkali glass and alkali glass, quartz, metallic foil comprising aluminium, stainless and the like, or a humidity resistance film.

Example of a humidity resistance film is described below.

The film which formed SiOx by CVD method on both sides of a plastic substrate, a laminated film comprising the film that transmissivity of moisture and oxygen is small, hydrophilic film, and the film which water absorption agent was applied to the film that transmissivity of moisture and oxygen is small.

It is preferable for moisture-vapor transmission of a humidity resistance film to be less than 10⁻⁶ g/m²/day.

Example of configuration of substrate for sealing can include configuration of a flat board, configuration of a film, cap configuration as referred to as a can for sealing.

After having applied adhesive to the second electrode side, substrate for sealing can be bonded to the second substrate. After having applied adhesive to the substrate side for sealing, substrate for sealing can be bonded to the second electrode.

In some embodiments, adhesive is applied to a whole area of the substrate side for sealing. Under vacuum or dry inert gas, substrate for sealing can be affixed to the second electrode of organic electroluminescence device afterwards.

When organic electroluminescence device is sealed with substrate for sealing and adhesive of thermoplastic resin is used, contact bonding by heating roller should be performed.

When heat curing type adhesion resin is used as adhesive, even more particularly, heating/hardening of adhesive should be done in cure temperature after contact bonding by heating roller.

When photo-curing type adhesion resin is used as adhesive, even more particularly, adhesive can be stiffened by an irradiation by light after contact bonding by roll.

In this way, sealed organic electroluminescence device can be obtained.

For example, as for the produced organic electroluminescence device, organic luminous layer 114 emits light by application of voltage of about 10V. The transparent electrode which is the first electrode can be used as anode. The counter electrode which is the second electrode can be used as cathode as illustrated in FIG. 1C.

Character and image can be displayed by the whole of these pixels by control of applied voltage every pixel sectioned by an insulator layer.

### EXAMPLE 1

FIG. 1C is explained below.

Substrate 102 was a transparent glass substrate of 100 mm square. ITO transparence first electrode 104 of form of stripe of 800 μm pitch (line 700 μm wide, space 100 μm wide) was installed in substrate 102. Afterwards a photo-curing type photosensitive resin was applied to a whole area in the substrate provided with the first electrode. By exposure/development, insulator layer 106 that profile was reverse taper configuration was provided. Insulator layer 100 was form of stripe in 800 μm pitch. Insulator layer 100 was perpendicular to the first electrode. Height of insulator layer 100 is 2 μm.

Fluid dispersion for the formation of a hole transport layer was made as follows.

The water dispersion that density of poly (3,4-ethylenedioxy thiophene) presented in the following formula (1) and polystyrene sulfonate (PEDOT/PSS) was 1 wt % was prepared. By means of addition of non-ion detergent of higher alcohol system ether to this water dispersion, fluid dispersion for the hole transport layer formation was adjusted. EMULGEN 105 made of Kao Corporation was used as non-ion detergent. An addition amount of surface active agent is 0.5 wt % as against PEDOT/PSS. And hole transport layer 112 was formed on the substrate with the first electrode and the insulator layer by applying provided fluid dispersion by means of slit coat method. Thickness of hole transport layer 112 is 80 nm. Substrate 234 was prepared in this way.

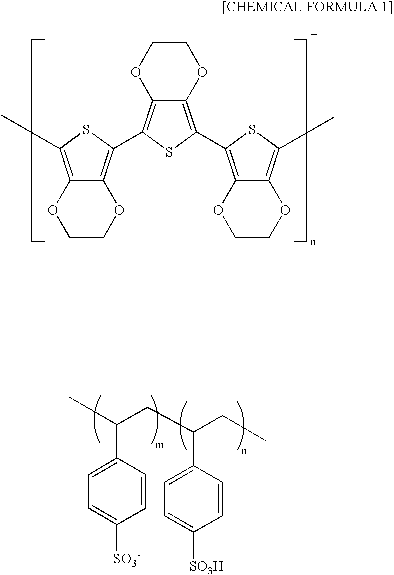

Organic luminescence ink is explained below next.

Cyclohexylbenzene was used as solvent. Macromolecule luminescent material MEH-PPV presented in the following formula (2) was dissolved in this solvent. Density of macromolecule luminescent material MEH-PPV is 1.3 wt %. And polystyrene (molecular weight Mw 1,000,000, a product made in Aldrich Corporation) was added as viscosity modifier. In organic luminescence ink after addition of viscosity modifier, the percentage that macromolecule luminescent material occupied in organic luminescence ink was 0.26 wt %. The viscosity of organic luminescence ink provided in this way was 25 mPa·s. The viscosity of organic luminescence ink was measured in rate of shear 100-200 s⁻¹ by rheometer.

In addition, viscosity mentioned in an example/comparative example as follows is measured by a similar method.

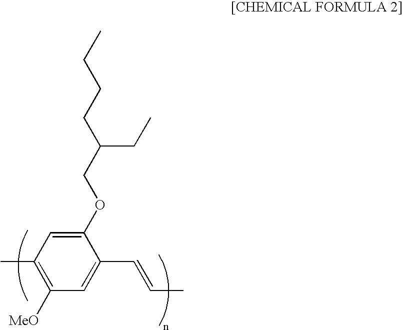

Next a printing material used for relief printing method was prepared.

On polyester film substrate, the water development type polyamide photosensitive resin layer was laminated. Ultraviolet radiation was irradiated on this resin through a mask. This resin was developed with water. In this way relief printing plate comprising substrate and water development type photosensitive resins was produced. A pattern of relief printing plate is form of stripe of L/S=700 μm/1,700 μm corresponding to insulator layer 106. When this relief printing plate was used, the same organic luminescence ink could be printed every three line.

And relief printing device in FIG. 2 having this relief printing plate was used, and the organic luminescence ink was printed in the shape of pattern on hole transport layer 112 on substrate 234. The organic luminescence ink was printed to domain sectioned to insulator layer 106. The thickness of provided organic luminous layer 114 was 80 nm. The thickness of this organic luminous layer 11 was uniform. In a like manner, printing plate of L/S=700 μm/1,700 μm was used, and printing of organic luminescence ink was performed twice, and the organic luminous layer was formed on all hole transport layers.

Subsequently, by “two-source evaporation method” of MgAg, second electrode 122 was formed. The thickness of second electrode 122 was 200 nm. In this way organic electroluminescence device 100 of passive driving type was made. In the second electrode formation side of organic electroluminescence device, photo-curing type adhesive was used, and glass cap was bonded, and it was sealed. Sealing is not illustrated.

In provided passive driving type organic electroluminescence device, leakage current did not occur. In addition, only all selected pixels turned on. The luminescence was 100 cd/m² at 5V. The luminescence was uniform.

### EXAMPLE 2

As for the substrate comprising the first electrode and an insulator layer and a hole transport layer, a substrate same as example 1 was prepared. Polyvinylcarbazole (molecular weight 118,000, a product made in Aldrich Corporation) was used as viscosity modifier to add in organic luminescence ink. This viscosity modifier was added in the cyclohexylbenzene solution that density of MEH-PPV was 1.3 wt %. The percentage of viscosity modifier in organic luminescence ink was 0.8 wt %. The viscosity of organic luminescence ink provided in this way was 18 mPa·s. In addition, other functional ink for relief printing was made same as example 1.

This organic luminescence ink was used, and organic luminous layer 114 was printed on substrate 234 same as example 1. The organic luminescence layer thickness was 80 nm. The thickness of the organic luminous layer was uniform. Then, second electrode 122 was provided with same as example 1. It was sealed. In this way organic electroluminescence device of passive driving type was made. In this organic electroluminescence device, leakage current did not occur.

In this organic electroluminescence device, only all selected pixels turned on. The luminescence was 80 cd/m² at 5V The luminescence was uniform.

### COMPARATIVE EXAMPLE 1

As for the substrate comprising the first electrode and an insulator layer and a hole transport layer, a substrate same as example 1 was prepared. Viscosity modifier (polystyrene) was not added into organic luminescence ink. Other functional ink for relief printing was made same as example 1. In other words the cyclohexylbenzene solution that density of MEH-PPV was 1.3 wt % was used. The viscosity of organic luminescence ink was 7 mPa·s.

Then, this organic luminescence ink was used, and the organic luminous layer was printed on a substrate same as example 1. Line pattern of organic luminescence ink formed on a substrate became too wide. Organic luminescence ink overflowed from an insulator layer. Organic luminescence ink has filled a neighboring pixel. Organic luminescence layer thickness was only 20 nm.

Then, the second electrode was provided with same as example 1. In this way organic electroluminescence device of passive driving type was made.

This organic electroluminescence device emitted light at 5V. However, the luminescence was only about 50 cd/m². In addition, a short circuit occurred immediately. In comparison between pixels in device, luminescence was nonuniform.

### COMPARATIVE EXAMPLE 2

As for the substrate comprising the first electrode and an insulator layer and a hole transport layer, a substrate same as example 1 was prepared. The cyclohexylbenzene solution that density of MEH-PPV was 0.8 wt % was made same as example 1. Subsequently polyvinylcarbazole (molecular weight 118,000, a product made in Aldrich Corporation) was added as viscosity modifier. Percentage of organic luminescent material in the whole organic luminescence ink was 1.8 wt %. Other functional ink for relief printing was prepared same as example 1. The viscosity of organic luminescence ink provided in this way was 78 mPa·s.

Then, this organic luminescence ink was used, and organic luminous layer 114 was printed on substrate 234 same as example 1. However, there was the ink which was not printed to a substrate.

What is claimed is:

1. A functional ink for relief printing comprising a solvent, one or more functional material(s), and a hole transport material or an electron transport material which dissolves in the solvent,
wherein the functional material is less than 2.5% by weight and more than 1.0% by weight in this functional ink, and
wherein viscosity of this ink is less than 50 mPa·s and more than 15 mPa·s at room temperature.

2. The functional ink for relief printing according to claim 1, wherein the ink further comprises a viscosity modifier.

3. Functional ink for relief printing according to claim 2, wherein the viscosity modifier is polystyrene or polyvinylcarbazole.

4. A manufacturing method of organic electroluminescence device comprising a substrate, first electrode, an insulator layer, an organic luminous layer a second electrode,
the method comprising:
forming the organic luminous layer by printing an organic luminescence ink including an organic luminescent material, dissolved in an organic solvent in area sectioned by the insulator layer on the substrate by relief printing method;
wherein the organic luminescent material is less than 2.5% by weight and more than 1.0% by weight in the organic luminescence ink,
and
wherein viscosity of this ink is less than 50 mPa·s and more than 15 mPa·s at room temperature.

5. A manufacturing method of organic electroluminescence device comprising a substrate, a first electrode, an insulator layer, an organic luminous media layer and a second electrode,
wherein the organic luminous media layer includes, as a functional layer, a organic luminous layer, a hole transport layer and/or an electron transport layer,
the method comprising:
forming at least one functional layer by printing a functional ink including a functional material, the functional material including an organic luminescent material, a hole transport material and/or electron transport material dissolved in an organic solvent in area sectioned by an insulator layer on the substrate;
wherein the functional material is less than 2.5% by weight and more than 1.0% by weight in the functional ink,
and
wherein viscosity of the functional ink is less than 50 mPa·s and more than 15 mPa·s at room temperature.

6. An organic electroluminescence device comprising a substrate, a first electrode, an insulator layer, an organic luminous media layer and a second electrode,
the organic luminous media layer comprising: an organic luminous layer;
and
a hole transport layer and/or electron transport layer,
which are functional layers, such that at least one of the functional layers comprises polystyrene or polyvinylcarbazole.
